(19) United States
(12) Patent Application Publication
(10) Pub. No.: US 2011/0169507 A1
(43) Pub. Date: Jul. 14, 2011

(54) METHODS AND APPARATUS FOR THE DETERMINATION OF MOISTURE CONTENT

(75) Inventors: Andreas Mershin, Cambridge, MA (US); Stella J. Karavas, Canton, MA (US); Yiannis G. Karavas, Canton, MA (US); Chris J. Lagadinos, Canton, MA (US); Patrick J. Moran, Shrewsbury, MA (US)

(73) Assignee: WHLK, LLC d/b/a Voltree Power, Canton, MA (US)

(21) Appl. No.: 12/987,037

(22) Filed: Jan. 7, 2011

Related U.S. Application Data
(60) Provisional application No. 61/293,531, filed on Jan. 8, 2010.

(51) Int. Cl. G01R 27/04

(52) U.S. Cl. 324/634

(57) ABSTRACT

Methods and apparatus for determining water content in a bulk heterogeneous material using electromagnetic radiation. A radiation source and a radiation receiver are positioned such that the material to be measured is located between them. As the radiation signal is transmitted from the source to the receiver, the signal experiences a path loss due, at least in part to the presence of the material located between the source and the receiver. The path loss in the transmitted signal, when recorded over time may be used to determine the water content of the material.

### RELATED APPLICATIONS

This application claims the benefit of U.S. Provisional Application Ser. No. 61/293,531 filed on Jan. 8, 2010, the contents of which are incorporated by reference herein.

### BACKGROUND

The water content of a material contributes to, among other things, the conductive properties of the material. Additionally, determining the water content of non-animal living organisms (e.g., trees) may be important to estimate the survival of the organism. However, current methods for determining water content in such materials are, under some circumstances, inaccurate and/or unreliable.

### SUMMARY

Some embodiments are directed to methods and apparatus for non-destructively determining the distribution of dielectric constants (∈) inside bulk heterogeneous materials using electromagnetic (EM) radiation of variable wavelengths and time-domain profiles. One or more radiation source(s), one or more radiation receiver(s) and a set of optional reflectors are positioned such that the material to be measured is traversed at least once by the emitted EM radiation. The total power as well as the power spectrum of the signal detected at the receiver is affected by path losses due to, in part, absorption of different portions of the emitted spectrum by materials of different (∈) due to the different dispersion relations of each. The total power, power spectrum and spatial distribution of the received signal may be used to determine the water content as well as the presence, concentration, and distribution of many other materials, contaminants etc. At its most complex, this general method and type of apparatus is capable of generating an accurate 3D map of the distribution of dielectric constants ∈(x,y,z) inside objects of various sizes, shapes and compositions non-invasively and non-destructively. A characteristic instance of application of this method and apparatus would be determining the water content of a tree. Automatic ranging, path determination and autocalibration are additional elements necessary for some of the apparatus and are also described herein.

One embodiment is directed to a method of measuring water content in a non-animal living organism. The method comprises transmitting with an electromagnetic radiation source, electromagnetic radiation through at least a portion of the organism; detecting with a receiver the transmitted electromagnetic radiation; and analyzing a path loss experienced by the detected electromagnetic radiation; and determining the water content based, at least in part, on the path loss.

Another embodiment is directed to a moisture-detection apparatus comprising: an electromagnetic radiation source configured to transmit electromagnetic radiation through at least a portion of a non-animal living organism; a receiver configured to receive the transmitted electromagnetic radiation; and at least one processor. The at least one processor is configured to: analyze a path loss experienced by the detected electromagnetic radiation; and determine an amount of moisture in the organism based, at least in part, on the path loss.

Another embodiment is directed to a moisture-detection system comprising: a non-animal living organism; an electromagnetic radiation source configured to transmit electromagnetic radiation through at least a portion of the organism; a receiver configured to receive the transmitted electromagnetic radiation; and at least one processor configured to analyze content of the transmitted electromagnetic radiation.

It should be appreciated that all combinations of the foregoing concepts and additional concepts discussed in greater detail below are contemplated as being part of the inventive subject matter disclosed herein.

### BRIEF DESCRIPTION OF THE DRAWINGS

FIG. 1 is a schematic diagram of a prior art passive tag that may be used to measure humidity or moisture provided it is pretreated and is in contact with a moisture source;

FIG. 2 is a schematic diagram of a moisture measuring device in accordance with some embodiments of the invention;

FIG. 3 is a plot of a measurement relating dielectric constants to moisture percentage in a material;

FIG. 4 is a schematic representation of a passive RFID device in accordance with some embodiments of the invention;

FIG. 5 is a circuit diagram of a passive RFID device in accordance with some embodiments of the invention;

FIG. 6 is a plot of resonance at the distal and proximal ends of the passive RFID device shown in FIG. 5;

FIG. 7 is a plot of a phase response of the passive RFID device shown in FIG. 5;

FIG. 8 is a schematic representation of a rotating linearly polarized wavefront emitted from an orthogonally fed patch radiator in accordance with some embodiments of the invention;

FIG. 9 is a schematic representation of a transmit and receive probe system in accordance with some embodiments of the invention;

FIG. 10 is a schematic representation of a method to resolve fine positions based on a Vernier effect in accordance with some embodiments of the invention; and

FIG. 11 illustrates schematic diagrams representing impedance of a reactive part of a probe in accordance with some embodiments of the invention.

### DETAILED DESCRIPTION

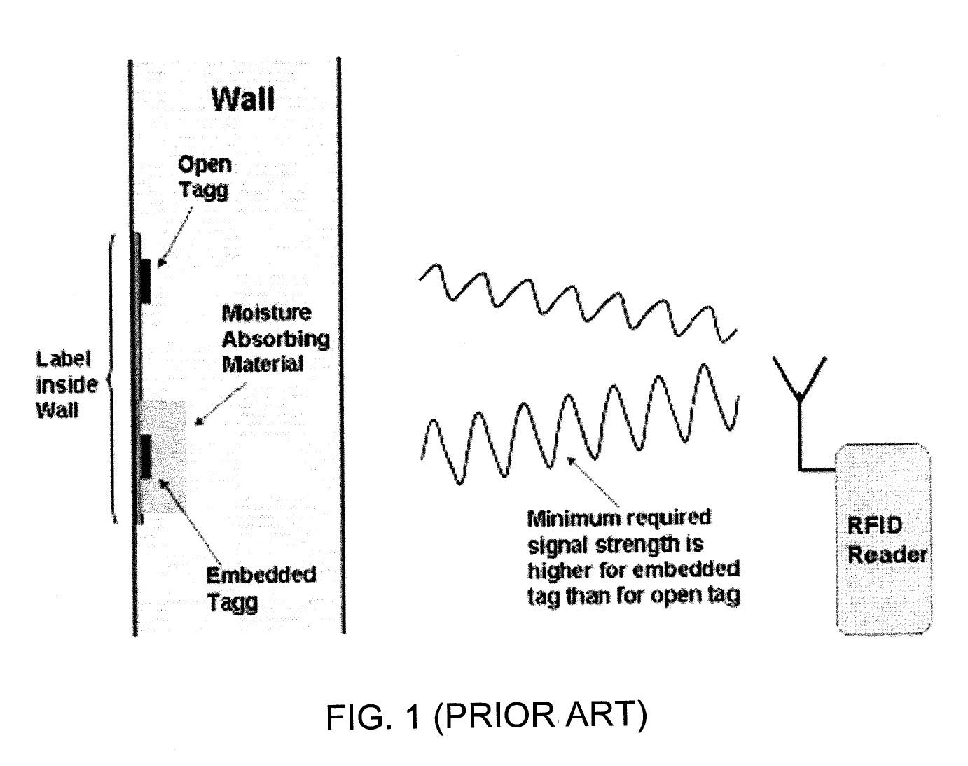

FIG. 1 illustrates a prior art passive tag for measuring humidity or moisture. However, such tags may only provide accurate readings if they are pre-treated and are in contact with the moisture source. The Applicants have recognized and appreciated that passive tags, such as those illustrated in FIG. 1 may be improved by developing an electromagnetic radiation system that may be used to determine the moisture content in objects non-invasively. Additionally, the Applicants have recognized and appreciated that moisture respiration in organic material may vary during the course of the growing season, and it may be desirable to measure the moisture content in situ without an disturbing or implanting measurement materials into the plants.

Applicants have recognized and appreciated that electromagnetic radiation (e.g., an EM wave or pulse) may be used to determine an amount of water content in various living and non-living bulk heterogeneous materials. In one embodiment, an radiation source and a radiation receiver (e.g., antenna) are positioned such that the material to be measured is located between them. As the radiation signal is transmitted from the source to the receiver, the signal experiences a path loss due, at least in part, to the presence of the material located between the source and the receiver. The path loss experienced by the EM wave or pulse can be characterized in the transmitted signal and when recorded over time may be used to determine the water content of the material.

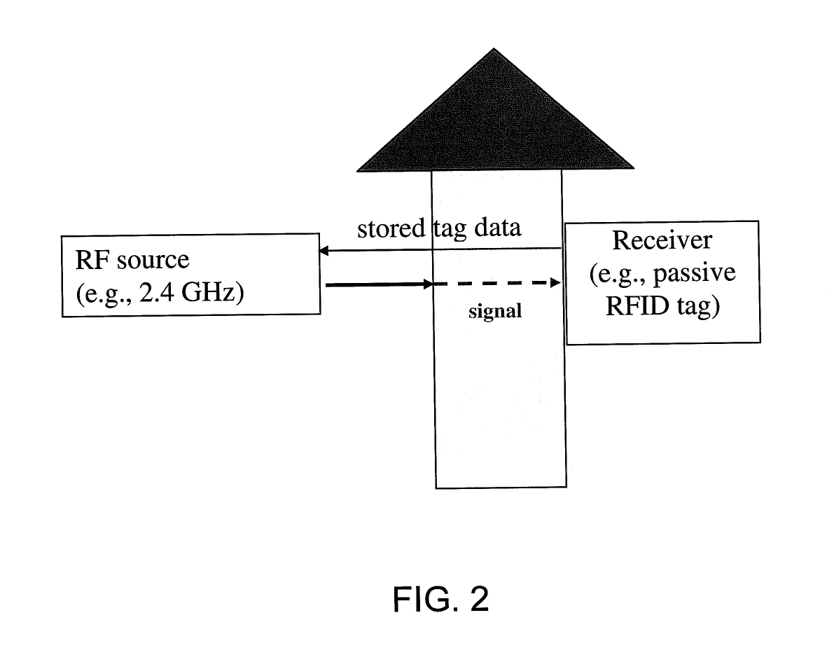

Some embodiments of the present disclosure are directed to a radio-frequency (RF) source configured to transmit electromagnetic radiation and a receiver (e.g., a passive RFID tag) configured to receive the transmitted radiation. The RF sources and receiver are positioned with at least one material placed between the source and the receiver as shown in FIG. 2. In the example shown in FIG. 2, an RFID device is placed on one side of a tree with an RF source (e.g., an RF scanner) placed on the other side of the tree. The attenuation of the RF signal between the source and the receiver is then determined. Although any transmission frequency in the microwave to radio frequency range may be used as the RF signal, a typical transmission frequency may be approximately 2.4 GHz, which is a frequency of noticeable water absorption. As the RF signal is transmitted from the source to the receiver, the signal will experience a path loss due, at least in part, to the presence of the material located between the source and the receiver. For example, the signal attenuation may be due to absorption and/or scattering of the RF signal as it passes through the material based on the properties of the material (e.g., the dielectric constant of the material).

Previously it has been described that the electric and magnetic fields of an electromagnetic wave propagating through a linear medium of uniform dielectric constant ∈ satisfy the equation:

$$( \frac{ɛ}{{c}^{2}} \frac{{\partial }^{2}}{\partial {t}^{2}} - {∇}^{2} ) \vec{E} = 0 \qquad ( Eq . 1 )$$

where the dielectric constant of vacuum is ∈ₒ=8.85×10⁻¹² F/m, and

$$∇ \times \vec{E} = - \frac{\partial \vec{B}}{\partial t} \qquad ( Eq . 2 )$$

with \vec{E}, \vec{B} being the electric and magnetic field vectors respectively and c being the speed of light in m/s.

The unitless relative dielectric constant κ may be defined as the ratio of the dielectric constant of any medium to that of vacuum:

κ=∈/∈ₒ (Eq. 3).

Some embodiments may be configured to detect moisture content in materials associated with values of κ ranging between 1 (e.g., for a vacuum) and 80 (e.g., for liquid water), although it should be appreciated that materials associated with other values of κ may also be used with some embodiments, as aspects of the invention are not limited in this respect.

Equations 1 and 2 admit the travelling plane wave solutions:

$$\begin{matrix}\vec{E} = {\vec{E}}_{o} {e}^{i ( \vec{k} \cdot \vec{r} - ω t )} \\ \vec{B} = {\vec{B}}_{o} {e}^{i ( \vec{k} \cdot \vec{r} - ω t ) ,} & ( Eq . 4 ) \\ with & \\ \frac{{ω}^{2}}{{k}^{2}} = \frac{{c}^{2}}{ɛ} and {B}_{o} = \frac{\vec{E} \times {\vec{E}}_{o}}{ω} , & ( Eq . 5 )\end{matrix}$$

where ω is the angular frequency of the EM wave (ω=2πf, where f is the frequency in Hz) and v is the “phase velocity” given by: v=ω/k=c/n, with n the index of refraction related to ∈ the dielectric constant via:

n=\sqrt{∈} (Eq. 6),

and k is the magnitude of the \vec{k} wave vector.

For some dielectric media, ∈ is a complex number indicating the possibility of attenuation or amplification of the wave as it interacts with the medium. Additionally, ∈ may be a function of frequency such that that materials of different ∈ exhibit different EM absorption, reflection, and amplification properties at different incident frequencies. That is, there may be a dispersion relation to the propagation of EM waves through dielectrics. Furthermore, some embodiments are directed to measuring moisture content in non-linear dielectric materials that change their dispersion relation as a function of the amplitude of the EM wave propagating through them.

The Applicants have recognized and appreciated that analyzing the dispersion relation for dielectric materials may be useful in determining the moisture content in non-animal organisms such as a tree. For a vast variety of dielectrics there exist specific frequency bands of very high absorption or other discernible spectral features. Therefore the presence of a material of specific κ (e.g., water of κ_{H2O}=80) inside another, heterogenous material of a different average κ, e.g. a piece of wood, may be determined. This may be accomplished, for example, by sending an EM wave of known spectral composition and power through the material in question in its dry state and recording the spectral composition and power of the transmitted wave, and then repeating the measurement with the object saturated with water. For the purposes of this example, it may only be necessary to know the distance between the transmitter and receiver. The two spectra (dry and wet) act as the zero and 100% water saturation calibration points and a time-resolved drying experiment (e.g., tracking the weight of the object) may be performed to determine the behavior of the transmitted EM wave at various moisture content percentages. A similar method may be applied to other materials (e.g., ethanol content in a aqueous solutions etc.).

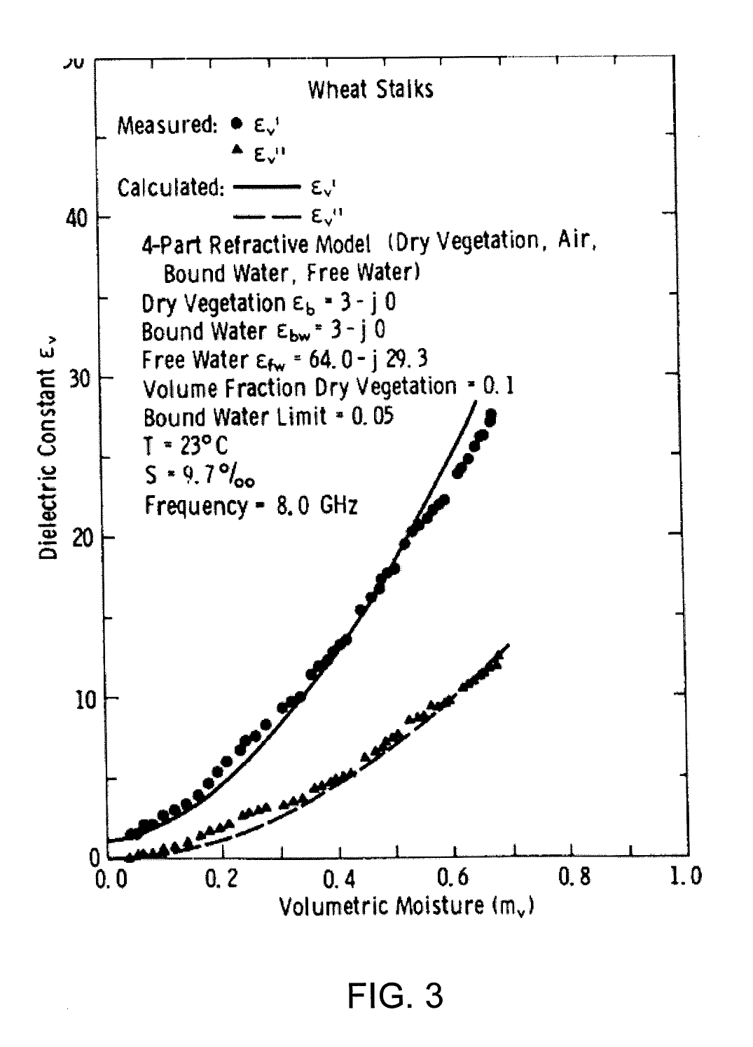

The concentration of water and the ionic content of the moisture in the plant material may influence dielectric constant of the bulk material. The effect of the moisture content on the dielectric constant has been measured by Ulaby et. al., as shown in FIG. 3. The path loss of an electromagnetic signal may be characterized using models (e.g., Weissberger and ITU Vegetation Model) derived from the free-space propagation equation. Such models may empirically relate the loss due to foliage (in dB) with an exponential decay function including the transmission frequency and the depth of foliage along the path. The path loss may also be a function of the distance between the receiver and the source. In some embodiments the diameter of the tree may be measured and uniform signal propagation through a cylinder may be assumed when calculating the percentage of total signal received. By examining the attenuation at certain frequencies, the water content of the material between the source and the receiver may be determined.

In some embodiments, the attenuation of the RF source may be used to measure the water content of trees. In such embodiments, the path loss may be recorded over time and the recorded data may be analyzed to determine the water content of the trees in the path of the RF signal. That is, as the water content of the trees increases, the path loss increases and vice versa.

In some embodiments, by examining the attenuation at a particular frequency of interest (e.g., 2 GHz), the amount of signal attenuation due to water absorption in the tree may be determined.

In some embodiments, contributions from humidity changes may be considered and accounted for in the water content analysis. Humidity may be determined in an suitable way including, but not limited to using one or more relative humidity sensors. In some embodiments, moisture on the source and receiver surfaces may be reduced using hydrophobic coatings.

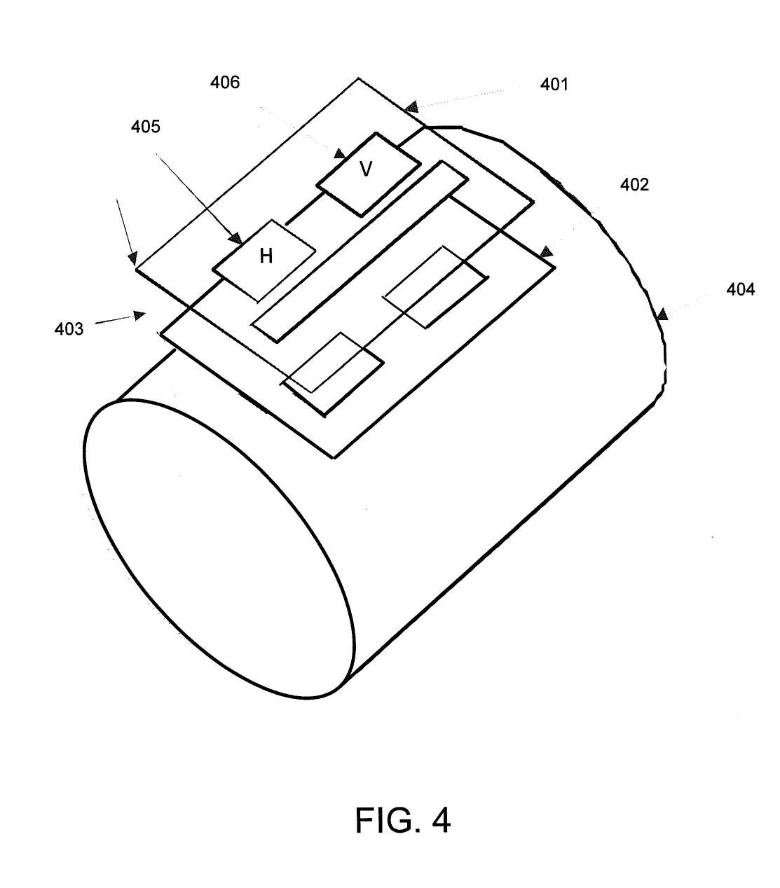

In some embodiments, an RFID device is placed in proximity to the tree or other plant material to provide a proximal and distal end such that the proximal end of the tag is near the material whose dielectric constant is to be measured. FIG. 4 illustrates an exemplary double polarized passive RFID tag 400 that may be placed on or near a test sample in accordance with some embodiments. The RFID tag 400 includes a first sensor 401 and a second sensor 402 separated by a small distance 403. The RFID tag 400 may be placed in proximity to the material 404 under test. The RFID device may include vertical patch 406 and horizontal patch 405 in the first sensor 401, sandwiching the second sensor 402, whose proximal end may be placed near the material 404 under test.

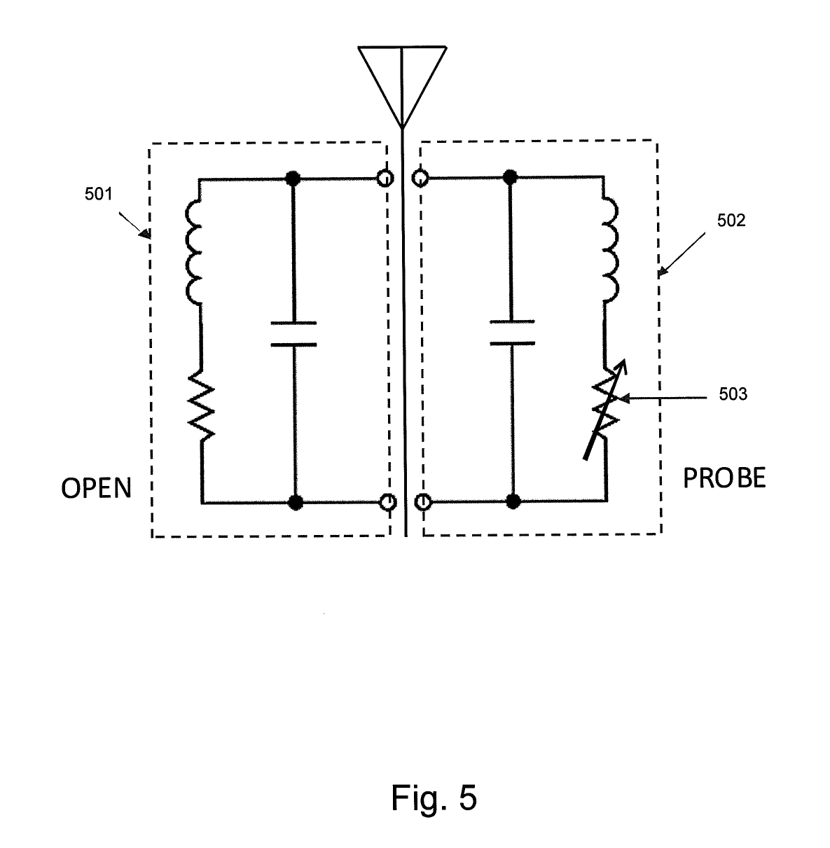

A schematic representation of a passive RFID device in accordance with some embodiments of the invention is shown in FIG. 5. The passive RFID device includes low resonant structure 501 and high resonant structure 502. The proximal end 503 of the passive RFID device may be used as a material probe.

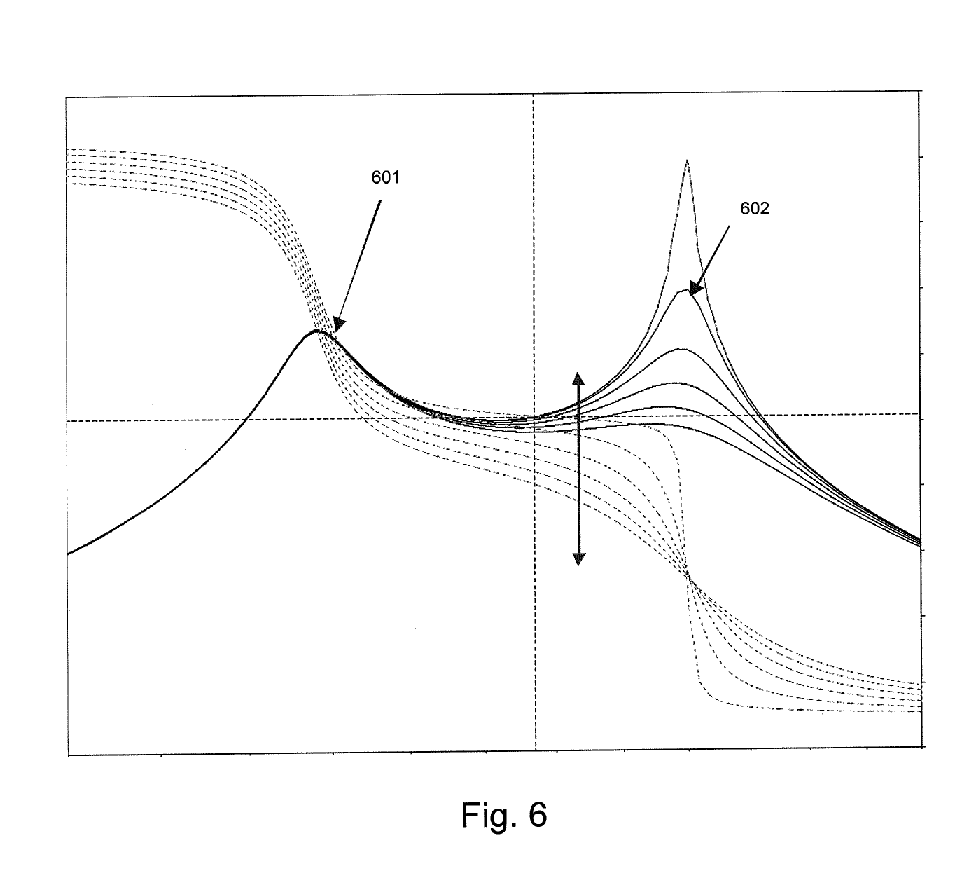

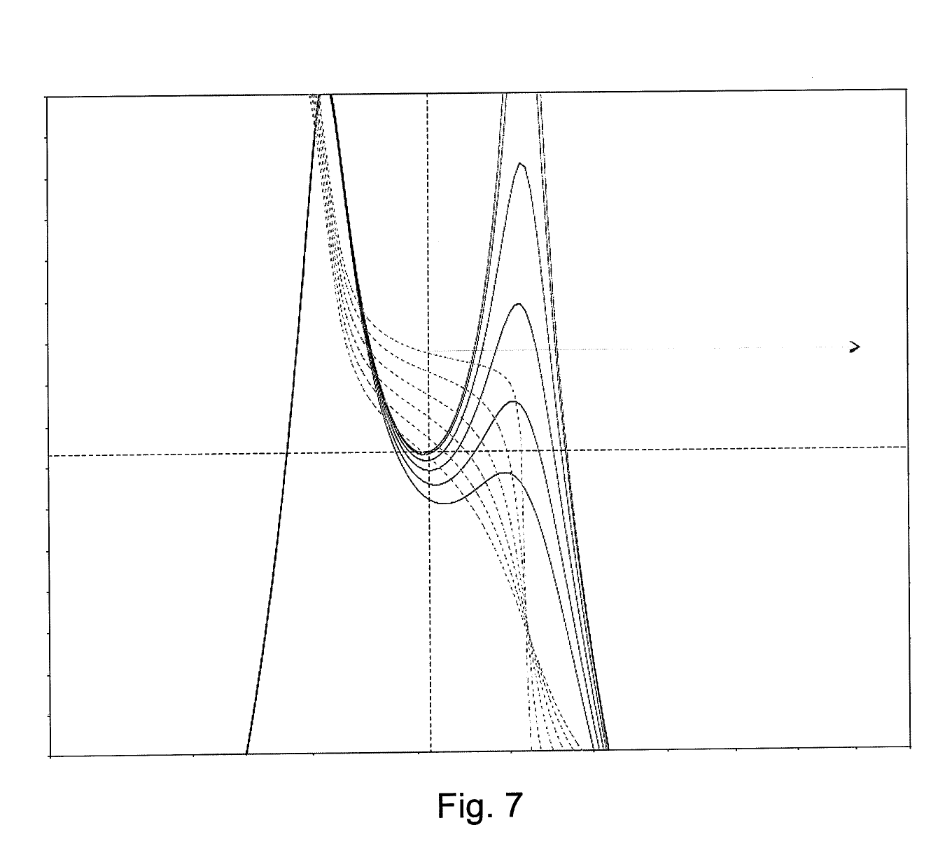

In some embodiments, the resonant frequency of the device is designed to operate slightly above and slightly below the provided EM frequency. In the case where there is a distal end of the device that is influenced by the complex dielectric constant of the test material, the loss factor due to the complex dielectric coefficient may affect the resonant phase of the Doublet as shown in FIGS. 6 and 7. A phase discrimination may be utilized to relate the transmitted to received phase of the backscattered waveform from the passive RFID device. FIG. 6 shows an example resonance of the Doublet at the distal end 601 and the proximal end 602 and the plot illustrates the effect of a complex dielectric material on the phase of the resulting backscatter waveform. FIG. 7 shows the magnitude and phase response of a Doublet resonator under various dielectric loss tangents. As is evident from FIG. 7, the phase response of the Doublet resonator depends on the loss component of the proximal probe.

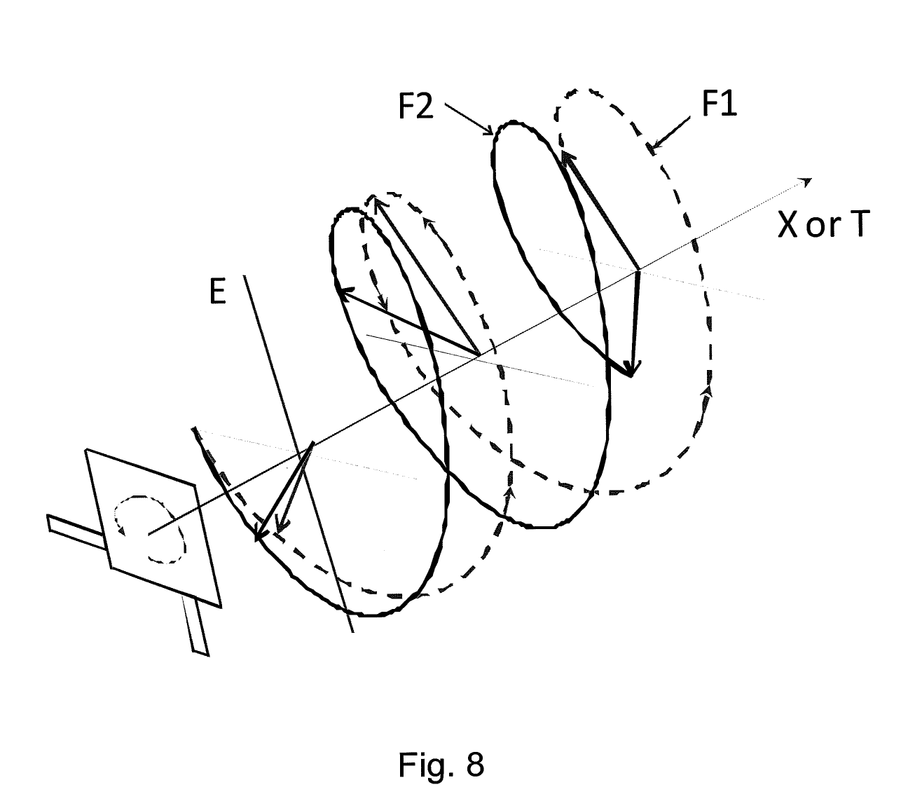

The phase of the backscattered waveform may be dependent on the distance between the interrogator device and the passive RFID device. In some embodiments, the distance to the RFID device may be determined by an imposition of a circular rotating phase Vernier as shown in FIG. 8. FIG. 8 illustrates a rotating linearly polarized wavefront emitted from an orthogonally fed patch radiator. The polarization is represented by F1 for the first rotating frequency and F2 for the second frequency. In such embodiments, a first rotation rate (e.g., F1) may be used to interrogate the RFID device, the phase of the backscatter waveform may be measured, and a second rotation rate (e.g., F2) may be used to measure the RFID device. The phase of the backscatter waveform may then be measured again.

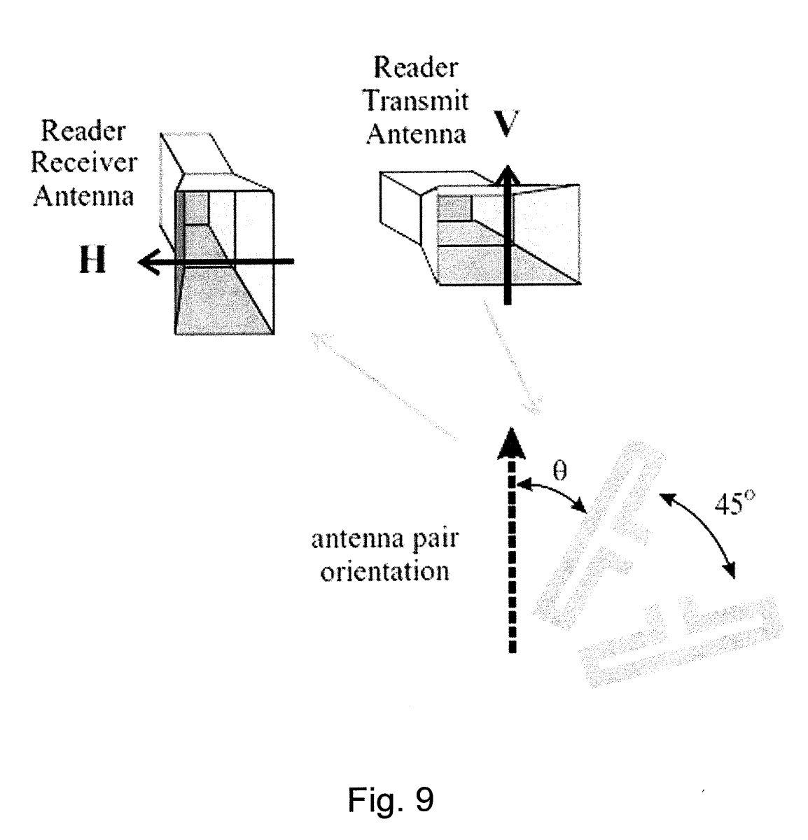

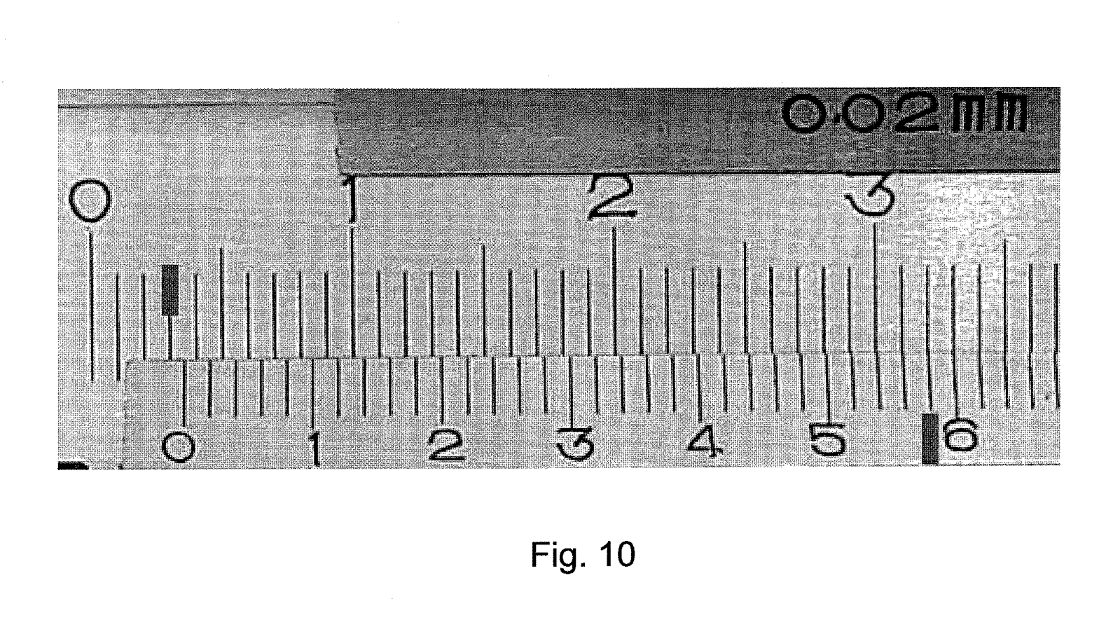

By knowing the relationship between the polarized patches on the RFID device and the spatial propagation relationship of the Vernier wavefronts, the absolute distance to the RFID device may be measured with a certain degree of accuracy. This is exemplified by FIGS. 9 and 10. FIG. 9 is a schematic representation of transmit and receive probes that are orthogonally polarized such that the orientation of the passive probe is sensitive to one polarization or the other. Such a probe may be used to determine the distance to a passive RFID tag. FIG. 10 illustrates a method to resolve a fine position based on a Vernier effect along a ruled edge.

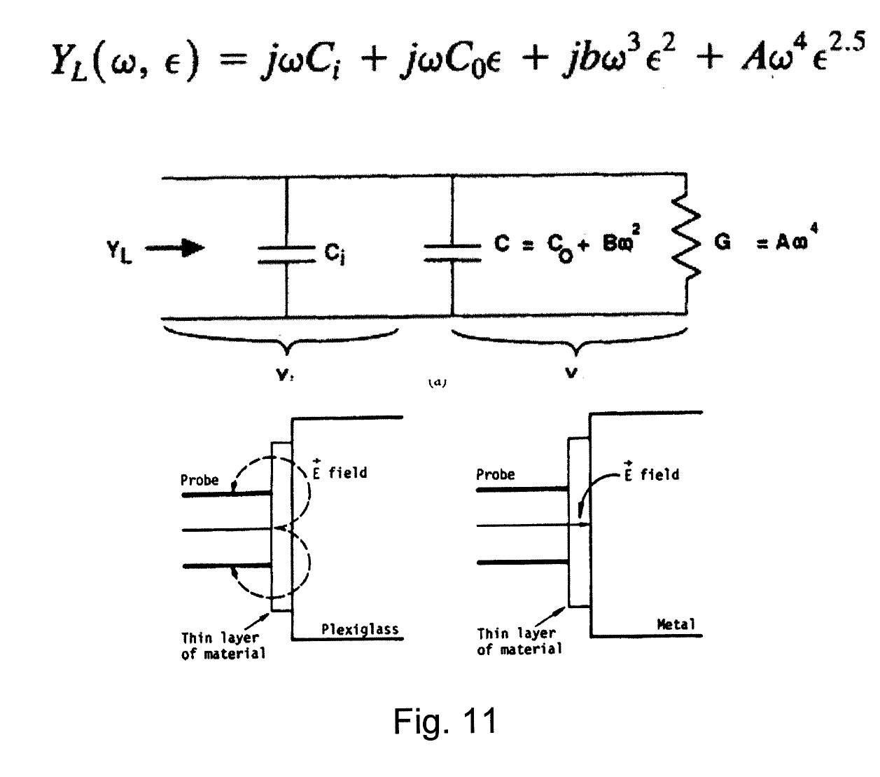

As described by Ulaby et. al., FIG. 11 illustrates an equation of the impedance of the reactive part of the proximal probe of an RFID device in accordance with some embodiments of the invention. The end effect of the resonant probe is shown in the extreme case where the stray field is either open or shorted.

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers. It should be appreciated that any component or collection of components that perform the functions described above can be generically considered as one or more controllers that control the above-discussed functions. The one or more controllers can be implemented in numerous ways, such as with dedicated hardware, or with general purpose hardware (e.g., one or more processors) that is programmed using microcode or software to perform the functions recited above.

In this respect, it should be appreciated that one implementation of the embodiments of the present invention comprises at least one non-transitory computer-readable storage medium (e.g., a computer memory, a floppy disk, a compact disk, a tape, etc.) encoded with a computer program (i.e., a plurality of instructions), which, when executed on a processor, performs the above-discussed functions of the embodiments of the present invention. The computer-readable storage medium can be transportable such that the program stored thereon can be loaded onto any computer resource to implement the aspects of the present invention discussed herein. In addition, it should be appreciated that the reference to a computer program which, when executed, performs the above-discussed functions, is not limited to an application program running on a host computer. Rather, the term computer program is used herein in a generic sense to reference any type of computer code (e.g., software or microcode) that can be employed to program a processor to implement the above-discussed aspects of the present invention.

Various aspects of the present invention may be used alone, in combination, or in a variety of arrangements not specifically discussed in the embodiments described in the foregoing and are therefore not limited in their application to the details and arrangement of components set forth in the foregoing description or illustrated in the drawings. For example, aspects described in one embodiment may be combined in any manner with aspects described in other embodiments.

Also, embodiments of the invention may be implemented as one or more methods, of which an example has been provided. The acts performed as part of the method(s) may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed. Such terms are used merely as labels to distinguish one claim element having a certain name from another element having a same name (but for use of the ordinal term).

The phraseology and terminology used herein is for the purpose of description and should not be regarded as limiting. The use of “including,” “comprising,” “having,” “containing”, “involving”, and variations thereof, is meant to encompass the items listed thereafter and additional items.

Having described several embodiments of the invention in detail, various modifications and improvements will readily occur to those skilled in the art. Such modifications and improvements are intended to be within the spirit and scope of the invention. Accordingly, the foregoing description is by way of example only, and is not intended as limiting. The invention is limited only as defined by the following claims and the equivalents thereto.

What is claimed is:

1. A method of measuring water content in a non-animal living organism, the method comprising:
transmitting with an electromagnetic radiation source, electromagnetic radiation through at least a portion of the organism;
detecting with a receiver the transmitted electromagnetic radiation;
analyzing a path loss experienced by the detected electromagnetic radiation; and
determining the water content based, at least in part, on the path loss.

2. The method of claim 1, wherein the non-animal living organism is a tree.

3. The method of claim 1, wherein the receiver is a passive radio-frequency identification (RFID) tag.

4. The method of claim 1, wherein the electromagnetic radiation is an electromagnetic wave.

5. The method of claim 1, wherein the electromagnetic radiation is an electromagnetic pulse.

6. A moisture-detection apparatus comprising:
an electromagnetic radiation source configured to transmit electromagnetic radiation through at least a portion of a non-animal living organism;
a receiver configured to receive the transmitted electromagnetic radiation; and
at least one processor configured to:
analyze a path loss experienced by the detected electromagnetic radiation; and
determine an amount of moisture in the organism based, at least in part, on the path loss.

7. The moisture-detection apparatus of claim 6, wherein the electromagnetic source is a radiofrequency (RF) scanner and the receiver is a passive RFID device.

8. The moisture-detection apparatus of claim 7, wherein the passive RFID device comprises a double polarized passive RFID tag.

9. The moisture-detection apparatus of claim 7, wherein the passive RFID device comprises at least one low resonance structure and at least one high resonance structure.

10. The moisture-detection apparatus of claim 6, further comprising:
at least one humidity sensor configured to detect a humidity value proximate to the organism;
wherein the processor is further configured to:
analyze the path loss based, at least in part, on the detected humidity value.

11. The moisture-detection apparatus of claim 6, wherein the electromagnetic source and the receiver are orthogonally polarized with respect to each other.

12. The moisture-detection apparatus of claim 6, wherein the non-living animal organism is a tree.

13. The moisture-detection apparatus of claim 6, wherein the receiver is not in contact with the organism.

14. The moisture-detection apparatus of claim 6, wherein the electromagnetic radiation is an electromagnetic wave.

15. The moisture-detection apparatus of claim 6, wherein the electromagnetic radiation is an electromagnetic pulse.

16. The moisture-detection apparatus of claim 6, wherein the processor is further configured to analyze the path loss at a particular frequency.

17. The moisture-detection apparatus of claim 16, wherein the particular frequency is 2.4 GHz.

18. A moisture-detection system comprising:
a non-animal living organism;
an electromagnetic radiation source configured to transmit electromagnetic radiation through at least a portion of the organism;
a receiver configured to receive the transmitted electromagnetic radiation; and
at least one processor configured to analyze content of the transmitted electromagnetic radiation.

19. The moisture-detection system of claim 18, wherein the at least one processor is further configured to analyze content of the transmitted electromagnetic radiation by determining a path loss of the transmitted radiation.

20. The moisture-detection system of claim 19, wherein the at least one processor is further configured to determine an amount of moisture content in the organism based, at least in part, on the path loss.
